(19) United States
(12) Patent Application Publication
(10) Pub. No.: US 2023/0397424 A1
(43) Pub. Date: Dec. 7, 2023

(54) MICROELECTRONIC DEVICES COMPRISING A BORON-CONTAINING MATERIAL, AND RELATED ELECTRONIC SYSTEMS AND METHODS

(71) Applicant: Micron Technology, Inc., Boise, ID (US)

(72) Inventors: Jordan D. Greenlee, Boise, ID (US); Everett A. McTeer, Eagle, ID (US); Rita J. Klein, Boise, ID (US); John D. Hopkins, Meridian, ID (US); Nancy M. Lomeli, Boise, ID (US); Xiao Li, Boise, ID (US); Christopher R. Ritchie, Boise, ID (US); Alyssa N. Scarbrough, Boise, ID (US); Jiewei Chen, Meridian, ID (US); Sijia Yu, Singapore (SG); Naiming Liu, Boise, ID (US)

(21) Appl. No.: 18/324,084

(22) Filed: May 25, 2023

Related U.S. Application Data
(60) Provisional application No. 63/365,650, filed on Jun. 1, 2022.

(51) Int. Cl. H10B 43/27; H10B 41/27

(52) U.S. Cl. CPC H10B 43/27; H10B 41/27

(57) ABSTRACT

A microelectronic device comprises a stack structure, a memory pillar, and a boron-containing material. The stack structure comprises alternating conductive structures and dielectric structures. The memory pillar extends through the stack structure and defines memory cells at intersections of the memory pillar and the conductive structures. The boron-containing material is on at least a portion of the conductive structures of the stack structure. Related methods and electronic systems are also described.

### CROSS-REFERENCE TO RELATED APPLICATIONS

This application claims the benefit under 35 U.S.C. §119(e) of U.S. Provisional Patent Application Ser. No. 63/365,650, filed Jun. 1, 2022, the disclosure of which is hereby incorporated herein in its entirety by this reference. The subject matter of this application is also related to the subject matter of U.S. Application Ser. No. 63/365,646, filed Jun. 1, 2022, titled “MICROELECTRONIC DEVICES COMPRISING A BORON-CONTAINING MATERIAL, AND RELATED ELECTRONIC SYSTEMS AND METHODS.”

### TECHNICAL FIELD

Embodiments of the disclosure relate to the field of electronic device design and fabrication. More specifically, embodiments of the disclosure relate to microelectronic devices including a boron-containing material, related electronic systems, and methods of fabricating such microelectronic devices and systems.

### BACKGROUND

Microelectronic device designers often desire to increase the level of integration or density of features within a microelectronic device by reducing the dimensions of the individual features and by reducing the separation distance between neighboring features. In addition, microelectronic device designers often seek to design architectures that are not only compact, but offer performance advantages, as well as simplified designs. Reducing the dimensions and spacing of features has placed increasing demands on the methods used to form the microelectronic devices. One solution has been to form three-dimensional (3D) microelectronic devices, such as 3D NAND devices, in which memory cells are positioned vertically on a substrate. An example of a conventional vertical memory array includes strings of memory cells vertically extending through stack structures that include tiers of conductive structures and dielectric structures. Each string of memory cells may include at least one select device coupled thereto. Such a configuration permits a greater number of switching devices (e.g., transistors) to be located in a unit of die area (i.e., length and width of active surface occupied) by building the memory array upwards (e.g., longitudinally, vertically) on the substrate, as compared to structures with conventional planar (e.g., two-dimensional) arrangements of transistors. The increasing complexity of the microelectronic devices, such as 3D NAND devices, introduces challenges in forming such devices. For example, complex microelectronic devices may be prone to defects during and after formation.

### BRIEF DESCRIPTION OF THE SEVERAL VIEWS OF THE DRAWINGS

FIG. 1 is a simplified, partial cross-sectional view of a microelectronic device, in accordance with embodiments of the disclosure.

FIG. 2 is an enlarged view of a portion of the microelectronic device of FIG. 1, in accordance with embodiments of the disclosure.

FIGS. 3A through 3E are simplified, partial cross-sectional views illustrating the microelectronic device of FIGS. 1 and 2 at different processing stages of a method of forming the microelectronic device, in accordance with embodiments of the disclosure.

FIG. 4 is a simplified, partial cross-sectional view of a microelectronic device, in accordance with embodiments of the disclosure.

FIG. 5 is a simplified, partial cross-sectional view of a microelectronic device, in accordance with embodiments of the disclosure.

FIG. 6 is a partial cutaway perspective view of a microelectronic device, in accordance with embodiments of the disclosure.

FIG. 7 is a functional block diagram of an electronic system, in accordance with embodiments of the disclosure.

### DETAILED DESCRIPTION

The following description provides specific details, such as material types, material thicknesses, and processing conditions in order to provide a thorough description of embodiments of the disclosure. However, a person of ordinary skill in the art will understand that the embodiments of the disclosure may be practiced without employing these specific details. Indeed, the embodiments of the disclosure may be practiced in conjunction with conventional fabrication techniques employed in the industry. In addition, the description provided below does not form a complete process flow for manufacturing a microelectronic device or electronic system. The structures described below do not form a complete microelectronic device or electronic system. Only those process acts and structures necessary to understand the embodiments of the disclosure are described in detail below. Additional acts to form a complete microelectronic device or electronic system from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

The use of the term “for example,” means that the related description is explanatory, and though the scope of the disclosure is intended to encompass the examples and legal equivalents, the use of such terms is not intended to limit the scope of an embodiment or this disclosure to the specified components, acts, features, functions, or the like.

As used herein, the term “microelectronic device” includes a device exhibiting memory functionality, but is not limited to microelectronic devices exhibiting memory functionality. Stated another way, and by way of example only, the term “microelectronic device” includes conventional memory (e.g., conventional volatile memory, such as conventional dynamic random access memory (DRAM); conventional non-volatile memory, such as conventional NAND memory), and an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, material distribution, orientation, and arrangement of one or more of at least one structure and at least one apparatus facilitating operation of one or more of the structure and the apparatus in a predetermined way.

As used herein, the phrase “coupled to” refers to structures operatively connected with each other, such as electrically connected through a direct Ohmic connection or through an indirect connection (e.g., by way of another structure).

As used herein, the singular forms “a,” “an,” and “the” are intended to include the plural forms as well, unless the context clearly indicates otherwise.

As used herein, “and/or” includes any and all combinations of one or more of the associated listed items.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, reference to a feature as being “on” an additional feature means and includes the feature being directly on top of, adjacent to (e.g., horizontally adjacent to, vertically adjacent to), underneath, or in direct contact with the additional feature. It also includes the element being indirectly on top of, adjacent to (e.g., horizontally adjacent to, vertically adjacent to), underneath, or near the additional feature, with one or more other features located therebetween. In contrast, when an element is referred to as “contacting” another element, there are no intervening features therebetween.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

Unless the context indicates otherwise, the materials described herein may be formed by any suitable process including, but not limited to, spin coating, blanket coating, chemical vapor deposition (“CVD”), atomic layer deposition (“ALD”), plasma enhanced ALD, physical vapor deposition (“PVD”) (including sputtering, evaporation, ionized PVD, and/or plasma-enhanced CVD (PECVD)), or epitaxial growth. Alternatively, the materials may be grown in situ. Depending on the specific material to be formed, the technique for depositing or growing the material may be selected by a person of ordinary skill in the art. In addition, unless the context indicates otherwise, the removal of materials described herein may be accomplished by any suitable process including, but not limited to, etching (e.g., dry etching, wet etching, vapor etching), ion milling, abrasive planarization (e.g., chemical-mechanical planarization (“CMP”)), and/or other known methods.

As used herein, “dielectric material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, a dielectric material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, a “dielectric structure” means and includes a structure formed of and including one or more dielectric materials.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Jr), nickel (Ni), palladium (Pa), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, a “high-k dielectric material” means and includes materials with a dielectric constant (k) greater than the dielectric constant of silicon dioxide (SiO₂). The high-k dielectric material may include a high-k oxide material, a high-k metal oxide material, or a combination thereof. By way of example only, the high-k dielectric material may be aluminum oxide, gadolinium oxide, hafnium oxide, niobium oxide, tantalum oxide, titanium oxide, zirconium oxide, hafnium silicate, a combination thereof, or a combination of one or more of the listed high-k dielectric materials with silicon oxide.

Microelectronic devices, and electronic systems described herein include a boron-containing material. A precursor of the boron-containing material may react with residues produced during formation of the microelectronic device, producing the boron-containing material on exposed surfaces (e.g., exposed surfaces within tiers) of the microelectronic device. By way of example only, the precursor may react with residues (e.g., chemical compounds) remaining within a stack structure of the microelectronic device following a removal process that removes sacrificial structures of the stack structure. Reaction products of the precursor and the residues may include the boron-containing material and gaseous products. The presence of the boron-containing material in the microelectronic device may help decrease nucleation delays of a barrier material at least partially (e.g., partially, substantially, entirely) surrounding conductive tiers of the stack structure. The presence of the boron-containing material may additionally inhibit and/or prevent diffusion of a halogen (e.g., fluorine, chlorine, bromine, iodine, or a combination thereof) species from the conductive structures of the stack structure to the dielectric structures of the stack structure. By inhibiting and/or preventing the diffusion of halogen species, the formation of reactive halide compounds is reduced (e.g., prevented). The boron-containing material may, therefore, reduce (e.g., prevent) the formation of voids within the dielectric structures of the stack structure, and may improve the performance and/or longevity of microelectronic devices, and electronic systems including the boron-containing material.

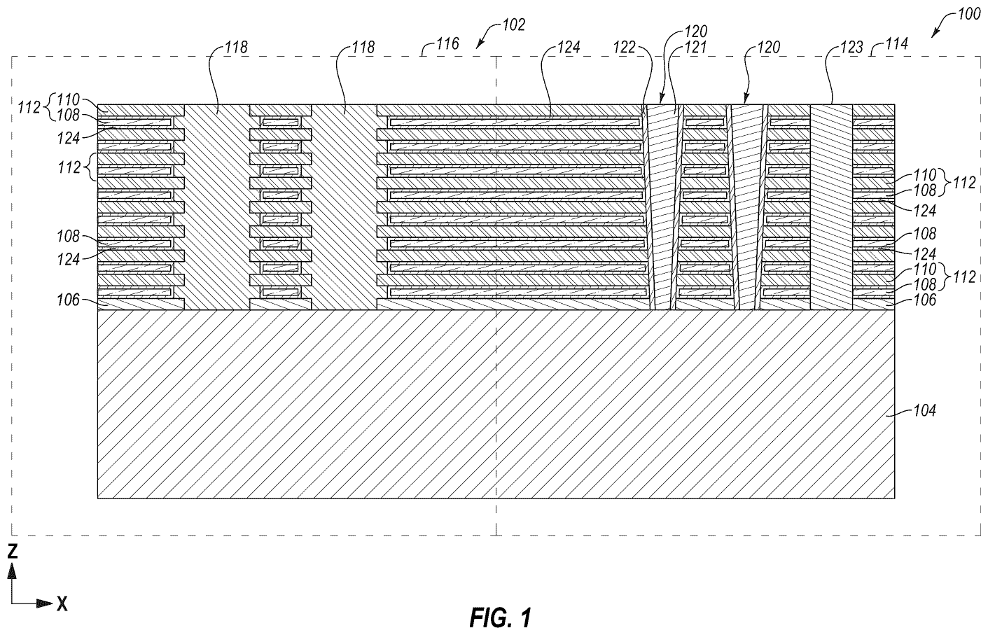

FIG. 1 is a simplified, partial cross-sectional view illustrating a microelectronic device 100, in accordance with embodiments of the disclosure. The microelectronic device 100 may, for example, be a 3D NAND Flash memory device, such as a multi-deck 3D NAND Flash memory device.

Referring now to FIG. 1, the microelectronic device 100 includes a stack structure 102 vertically neighboring (e.g., vertically adjacent to) a source 104. For example, the source 104 may be vertically underlying (e.g., in the Z-direction) the stack structure 102. The stack structure 102 may include a base material 106 vertically overlying (e.g., in the Z-direction) the source 104, and a vertically alternating (e.g., in the Z-direction) sequence of conductive structures 108 (e.g., access lines, word lines) and dielectric structures 110 arranged in tiers 112 on the base material 106.

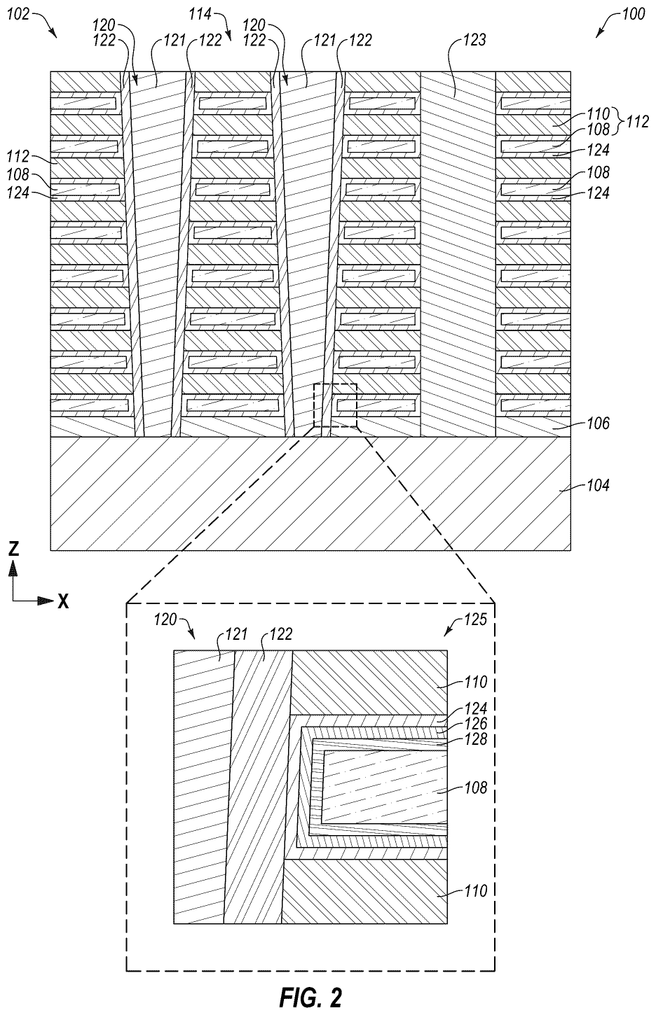

The microelectronic device 100 may additionally include a boron-containing material 124 neighboring the conductive structures 108, the dielectric structures 110, pillars 120 (e.g., the memory pillars 120) and/or a dielectric fill material 123. For example, the boron-containing material 124 may be between the conductive structures 108 of the stack structure 102 and the dielectric structures 110 of the stack structure 102. While FIG. 1 illustrates the boron-containing material 124 on surfaces of the conductive structures 108, additional materials may be present, including, but not limited to, a barrier material 126 and a liner material 128, shown and described below with reference to FIG. 2.

Continuing with reference to FIG. 1, the microelectronic device 100 includes an array region 114 and a contact region 116 adjacent to (e.g., in the X-direction) the array region 114. Within the contact region 116, the microelectronic device 100 includes one or more contact structures 118 (e.g., support structures or conductive contact structures) extending through the stack structure 102 to the source 104. While FIG. 1 illustrates the contact structures 118 as including a single material, multiple materials may be present, including, but not limited to, a conductive material, and one or more liner materials. Additionally, portions of the conductive structures 108 of the stack structure 102 may be horizontally recessed (e.g., in the X-direction and/or Y-direction) relative to the dielectric structures 110, and corresponding portions of the contact structures 118 may at least partially (e.g., partially, substantially, entirely) fill the recesses. In some embodiments, the contact structures 118 function as electrical interconnections. In additional embodiments, the contact structures 118 do not provide electrical interconnections and primarily (e.g., only) provide a support function. The contact region 116 of the microelectronic device 100, and the contact structures 118 of the contact region 116 may be formed by conventional techniques. Additionally, the contact structures 118 may comprise any suitable materials.

Adjacent to the contact region 116 is the array region 114. Within the array region 114, the microelectronic device 100 includes one or more memory pillars 120 (e.g., vertical strings of memory cells) extending through the stack structure 102. For simplicity, the memory pillars 120 illustrated in FIG. 1 include an interior fill material 121 and an exterior material (e.g., cell film materials 122) between the interior fill material 121 and sidewalls of the conductive structures 108 (e.g., access lines, word lines) and the dielectric structures 110. While FIG. 1 illustrates the cell film materials 122 as a single material for convenience, the cell film materials 122 may include one or more of a channel material, a tunnel dielectric material, a memory material (also referred to as a “charge-trap” material), and a charge-blocking material, as described in detail below with reference to FIG. 2. Within the array region, the microelectronic device 100 may also include the dielectric fill material 123 at least partially filling a recess that extends through the stack structure 102 to the source 104.

A majority of the stack structure 102 may be formed in a conventional manner and may comprise conventional materials. For example, the base material 106 and/or the dielectric structures 110 may be formed in a conventional manner and may comprise conventional materials.

The base material 106 may be formed of and include at least one dielectric material. The base material 106 of the stack structure 102 may be substantially planar, and may exhibit a desired thickness.

The dielectric structures 110 may comprise one or more dielectric materials. In some embodiments, the dielectric structures 110 comprise silicon dioxide. The dielectric structures 110 may each be substantially planar, and may each individually exhibit a desired thickness.

The conductive structures 108 may comprise one or more conductive materials. In some embodiments, the conductive structures 108 comprise tungsten. The conductive structures 108 of each of the tiers 112 of the stack structure 102 may each be substantially planar, and may each individually exhibit a desired thickness.

A conductive structure 108 of the stack structure 102 near (e.g., vertically adjacent to) the base material 106 may function as at least one lower select gate (e.g., at least one source side select gate (SGS)) of the microelectronic device 100. In some embodiments, a single (e.g., only one) conductive structure 108 of a vertically lowermost tier 112 of the stack structure 102 functions as a lower select gate (e.g., a SGS) of the microelectronic device 100. In addition, upper conductive structure(s) 108 of the stack structure 102 may function as upper select gate(s) (e.g., drain side select gate(s) (SGDs)) of the microelectronic device 100. In some embodiments, horizontally neighboring (e.g., in the X-direction or Y-direction) conductive structures 108 of a vertically uppermost tier 112 of the stack structure 102 may function as upper select gates (e.g., SGDs) of the microelectronic device 100.

Although FIGS. 1 and 2 illustrate a particular number of tiers 112 of the dielectric structures 110 and the conductive structures 108, the disclosure is not so limited. In some embodiments, the stack structure 102 includes a desired quantity of the tiers 112, such as greater than sixty-four (64) of the tiers 112 (e.g., greater than or equal to seventy (70) of the tiers 112, greater than or equal to one hundred (100) of the tiers 112, greater than or equal to about one hundred twenty-eight (128) of the tiers 112) of the dielectric structures 110 and the conductive structures 108. In addition, in some embodiments, the stack structure 102 overlies and/or underlies a deck structure (not shown) comprising additional tiers 112 of dielectric structures 110 and conductive structures 108, separated from the stack structure 102 by at least one dielectric material, such as an interdeck dielectric material (not shown).

The microelectronic device 100 further includes the source 104 vertically adjacent to the stack structure 102. For example, the source 104 may vertically underlie (e.g., in the Z-direction) the stack structure 102. The source 104 may comprise, for example, one or more conductive materials. In some embodiments, the source 104 comprises conductively-doped polysilicon.

FIG. 2 illustrates an enlarged view of the array region 114 of the microelectronic device 100, in accordance with embodiments of the disclosure. To avoid repetition, not all features shown in FIG. 2 are described in detail herein.

Although FIGS. 1 and 2 illustrate two memory pillars 120, the microelectronic device 100 includes two or more (e.g., multiple) memory pillars 120. The memory pillars 120 may be within (e.g., partially within, substantially within, entirely within) the stack structure 102.

Referring now to FIG. 2, the memory pillars 120 may vertically extend (e.g., in the Z-direction) through the stack structure 102 to the source 104. The memory pillars 120 may exhibit a desired geometric configuration (e.g., dimensions and shape). The geometric configuration of the memory pillars 120 may be selected at least partially based on the configurations and positions of other components of the microelectronic device 100 and positions of other memory pillars 120.

The memory pillars 120 may be spaced relative to other components of the microelectronic device 100, which may permit the memory pillars 120 to vertically-extend (e.g., in the Z-direction) through the stack structure 102 and physically contact (e.g., land on) the source 104 to facilitate a memory function of the memory pillars 120. Intersections between the materials of the memory pillars 120 and the conductive structures 108 of the stack structure 102 define memory cells 125, as shown within the enlarged portion of FIG. 2. However, the disclosure is not so limited, and the memory pillars 120 may be arranged in other patterns. For example, each of the memory pillars 120 may exhibit substantially the same geometric configuration (e.g., the same dimensions and the same shape) and horizontal spacing (e.g., in the X-direction) as each of the other memory pillars 120, or at least some of the memory pillars 120 may exhibit a different geometric configuration (e.g., one or more different dimensions, a different shape) and/or different horizontal spacing than at least some other of the memory pillars 120.

The memory pillars 120 include the interior fill material 121 and cell film materials 122 between the interior fill material 121 and sidewalls of the stack structure 102. The interior fill material 121 may include a dielectric material, such as silicon dioxide. The cell film materials 122 of the memory pillars 120, arranged from outermost material (e.g., closest to sidewalls of the stack structure 102) to innermost material (e.g., closest to the interior fill material 121), may include the charge-blocking material, the memory material, the tunnel dielectric material, and the channel material.

The charge-blocking material may be formed of and include a dielectric material. By way of example only, the charge-blocking material may be one or more of an oxide (e.g., silicon dioxide), a nitride (e.g., silicon nitride), and an oxynitride (e.g., silicon oxynitride), or another material. In some embodiments, the charge-blocking material is silicon dioxide.

The memory material may be formed of and include at least one memory material and/or one or more conductive materials. The memory material may be formed of and include one or more of silicon nitride, silicon oxynitride, polysilicon (e.g., doped polysilicon), a conductive material (e.g., tungsten, molybdenum, tantalum, titanium, platinum, ruthenium, and alloys thereof, or a metal silicide such as tungsten silicide, molybdenum silicide, tantalum silicide, titanium silicide, nickel silicide, cobalt silicide, or a combination thereof), a semiconductive material (e.g., polycrystalline or amorphous semiconductor material, including at least one elemental semiconductor element and/or including at least one compound semiconductor material, such as conductive nanoparticles (e.g., ruthenium nanoparticles) and/or metal dots). In some embodiments, the memory material is silicon nitride.

The tunnel dielectric material may include one or more dielectric materials, such as one or more of a silicon nitride material or a silicon oxide material. In some embodiments, the tunnel dielectric material is a so-called “ONO” structure that includes silicon dioxide, silicon nitride, and silicon dioxide. The channel may be formed of and include a semiconductive material, a non-silicon channel material, or other channel material. The material of the channel may include, but is not limited to, a polysilicon material (e.g., polycrystalline silicon), a III-V compound semiconductive material, a II-VI compound semiconductive material, an organic semiconductive material, GaAs, InP, GaP, GaN, an oxide semiconductive material, or a combination thereof. In some embodiments, the channel is polysilicon, such as a doped polysilicon. The channel may be configured as a so-called doped hollow channel (DHC) or other configuration.

As illustrated in FIG. 2, the memory pillars 120 extend through the stack structure 102 and define the memory cells 125 at intersections between the memory pillars 120 and the conductive structures 108. The enlarged portion of FIG. 2 illustrates a memory cell 125 of the microelectronic device 100, in accordance with embodiments of the disclosure. The memory cells 125 may each include the cell film materials 122 of the memory pillars 120 and the conductive structures 108 horizontally neighboring the cell film materials 122.

As can be seen within the enlarged portion of the memory cell 125, the microelectronic device 100 may include the boron-containing material 124 neighboring at least a portion (e.g., a portion, or the entirety) of the memory pillars 120, the conductive structures 108, and/or the dielectric structures 110. The microelectronic device 100 may additionally include the barrier material 126 between the conductive structures 108 of the stack structure 102 and the boron-containing material 124, and the liner material 128 on at least a portion of the conductive structures 108 between the conductive structures 108 and the boron-containing material 124. The boron-containing material 124 may at least partially (e.g., partially, substantially, entirely) surround the barrier material 126, the liner material 128, and the conductive structures 108 of the stack structures 102. For example, the boron-containing material 124 may directly contact surfaces (e.g., horizontal surfaces, vertical surfaces) of the dielectric structures 110 of the stack structure 102, may directly contact surfaces (e.g., vertical surfaces) of the memory pillars 120, and may further directly contact surfaces (e.g., horizontal surfaces, vertical surfaces) of the barrier material 126. The barrier material 126 may at least partially surround the liner material 128 and the conductive structures 108 of the stack structure 102. For example, the barrier material 126 may directly contact surfaces (e.g., horizontal surfaces, vertical surfaces) of the boron-containing material 124, and may also contact surfaces (e.g., horizontal surfaces, vertical surfaces) of the liner material 128. The liner material 128 may at least partially surround the conductive structures 108 of the stack structure 102. For example, the liner material 128 may directly contact surfaces (e.g., horizontal surfaces, vertical surfaces) of the barrier material 126, and may also directly contact surfaces (e.g., horizontal surfaces, vertical surfaces) of the conductive structures 108.

Although the barrier material 126 is illustrated as being interposed between the boron-containing material 124 and the liner material 128, the disclosure is not so limited. For example, the locations of the boron-containing material 124 and the barrier material 126 may be reversed such that the boron-containing material 124 is interposed between the barrier material 126 and the liner material 128. In such an arrangement, the barrier material 126 would contact the dielectric structures 110, the cell film materials 122 of the memory pillars 120, and at least partially surround the boron-containing material 124.

Continuing with reference to FIG. 2, the liner material 128 may vertically neighbor at least a portion (e.g., a portion, or the entirety) of the conductive structures 108 and the dielectric structures 110 of the stack structure 102. The liner material 128 may be between and separating the barrier material 126 from the conductive structures 108 of the stack structure 102. For example, the liner material 128 may be on at least a portion (e.g., a portion or the entirety) of horizontal surfaces and vertical surfaces of the conductive structures 108 of the stack structure 102. The liner material 128 may also be on at least a portion of horizontal surfaces and vertical surfaces of the barrier material 126. The liner material 128 may also horizontally neighbor at least a portion of the memory pillars 120, and/or the dielectric fill material 123. For example, the liner material 128 may be on at least a portion of vertical surfaces of the barrier material 126.

The liner material 128 may exhibit any desired thickness. For example, a the liner material 128 may exhibit a thickness within a range from about 0.5 nanometer (nm) to about 50 nm, such as from about 0.5 nm to about 1 nm, from about 1 nm to about 5 nm, from about 5 nm to about 10 nm, from about 10 nm to about 30 nm, or from about 30 nm to about 50 nm.

The liner material 128 may comprise, for example, a seed material from which or upon which the conductive structures 108 may be formed. The liner material 128 may be formed of and include, for example, a metal (e.g., titanium, tantalum), a metal nitride (e.g., tungsten nitride, titanium nitride, tantalum nitride), or another material.

The barrier material 126 may vertically neighbor at least a portion (e.g., a portion, or the entirety) of the conductive structures 108 and the dielectric structures 110 of the stack structure 102. The barrier material 126 may be between and separating the boron-containing material 124 from the liner material 128. For example, the barrier material 126 may be on at least a portion (e.g., a portion or the entirety) of horizontal surfaces and vertical surfaces of the liner material 128. The barrier material 126 may also be on at least a portion of horizontal surfaces of the boron-containing material 124. The barrier material 126 may horizontally neighbor at least a portion of the memory pillars 120, and/or the dielectric fill material 123. For example, the barrier material 126 may be on at least a portion of vertical surfaces of the boron-containing material 124.

The barrier material 126 may exhibit any desired thickness. For example, the barrier material 126 may exhibit a thickness within a range from about 0.5 nanometer (nm) to about 50 nm, such as from about 0.5 nm to about 1 nm, from about 1 nm to about 5 nm, from about 5 nm to about 10 nm, from about 10 nm to about 30 nm, or from about 30 nm to about 50 nm.

In some embodiments, the barrier material 126 may comprise a dielectric material. For example, the barrier material 126 may be formed of and include one or more of a metal oxide (e.g., one or more of aluminum oxide, hafnium oxide, zirconium oxide, lanthanum oxide, yttrium oxide, tantalum oxide, gadolinium oxide, niobium oxide, titanium oxide), a dielectric silicide (e.g., aluminum silicide, hafnium silicate, zirconium silicate, lanthanum silicide, yttrium silicide, tantalum silicide), and a dielectric nitride (e.g., aluminum nitride, hafnium nitride, lanthanum nitride, yttrium nitride, tantalum nitride). In some embodiments, the barrier material 126 comprises a high-k dielectric material. In additional embodiments, the barrier material 126 comprises a high-k oxide material. In further embodiments, the barrier material 126 comprises aluminum oxide.

The boron-containing material 124 may be on at least a portion of the dielectric structures 110, and may vertically neighbor (e.g., in the Z-direction) the conductive structures 108 of the stack structure 102. The boron-containing material 124 may be between and separating the dielectric structures 110 from the conductive structures 108 of the stack structure 102. Additionally, the boron-containing material 124 may be between and separating the barrier material 126 from the memory pillars 120 and the dielectric structures 110 of the stack structure 102. In some embodiments, the boron-containing material 124 at least partially surrounds and/or conforms to surfaces of the dielectric structures 110 and/or portions of the memory pillars 120 within the stack structure 102. For example, the boron-containing material 124 may be on at least a portion (e.g., a portion or the entirety) of horizontal surfaces of the dielectric structures 110, and may also be on at least a portion of horizontal surfaces and vertical surfaces of the barrier material 126. The boron-containing material 124 may also horizontally neighbor (e.g., in the X-direction) at least a portion of the conductive structures 108, the memory pillars 120, and/or the dielectric fill material 123. The boron-containing material 124 may be between and separating the memory pillars 120 from the conductive structures 108 of the stack structure 102. For example, the boron-containing material 124 may be on at least a portion of vertical surfaces of the cell film materials 122 of the memory pillars. In other words, the boron-containing material 124 may contact vertical surfaces of the charge-blocking material of the memory pillars 120. In addition, the boron-containing material 124 may be on at least a portion of vertical surfaces of the dielectric fill material 123.

In some embodiments, the boron-containing material 124 exhibits substantially uniform dimensions (e.g., thickness) in the X-direction, the Y-direction, and/or the Z-direction. For example, the boron-containing material 124 may exhibit a thickness of from about 1 nm to about 150 nm, such as from about 10 nm to about 100 nm or from about 25 nm to about 60 nm (e.g., about 40 nm). In some embodiments, the boron-containing material 124 exhibits a thickness of from about 1 nm to about 50 nm. Additionally, the boron-containing material 124 may conform to the geometry of the stack structure 102 between the dielectric structures 110 and/or portions of the memory pillars 120.

The boron-containing material 124 may be substantially homogeneous in chemical composition or substantially heterogeneous in chemical composition.

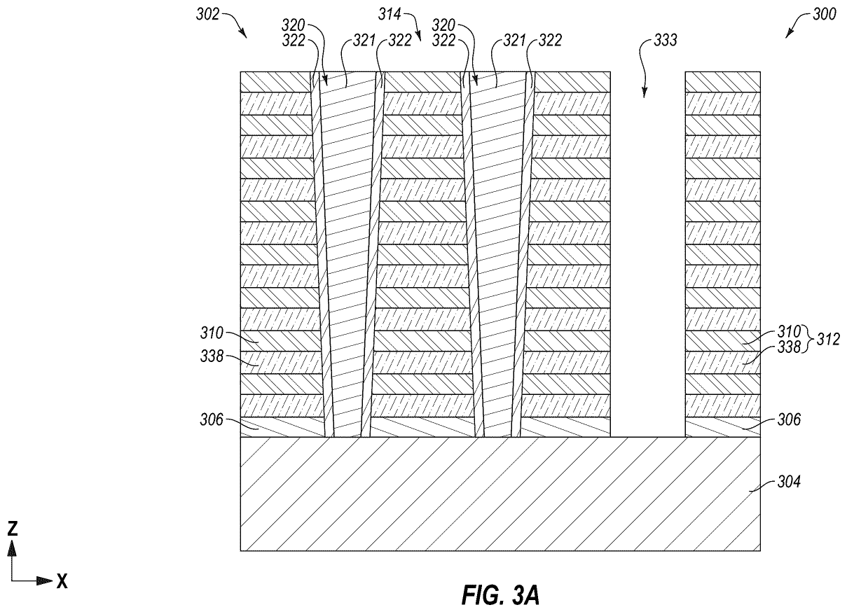

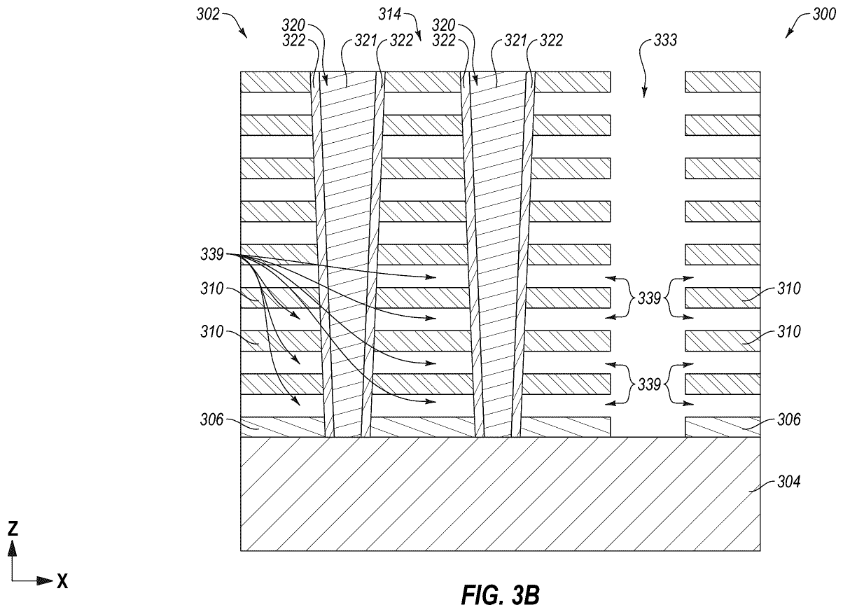

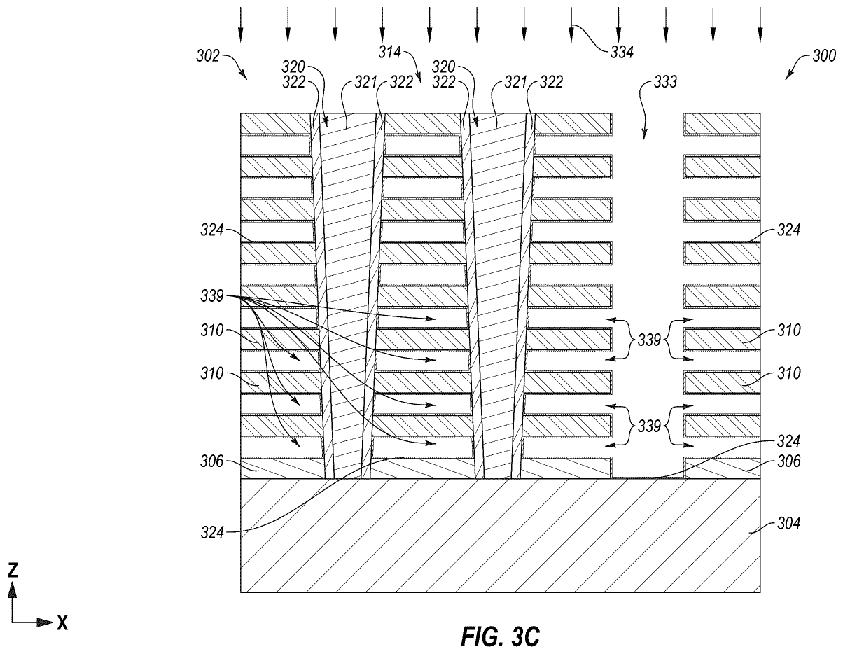

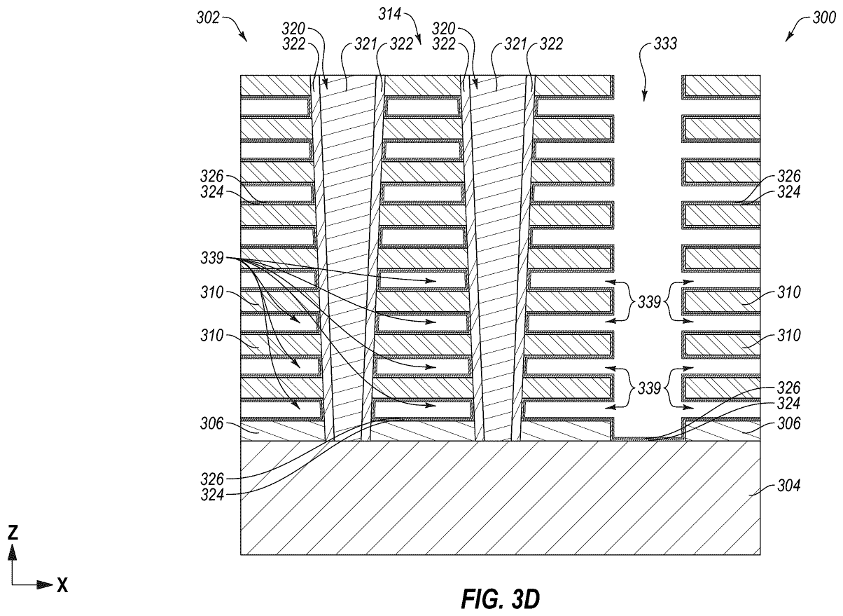

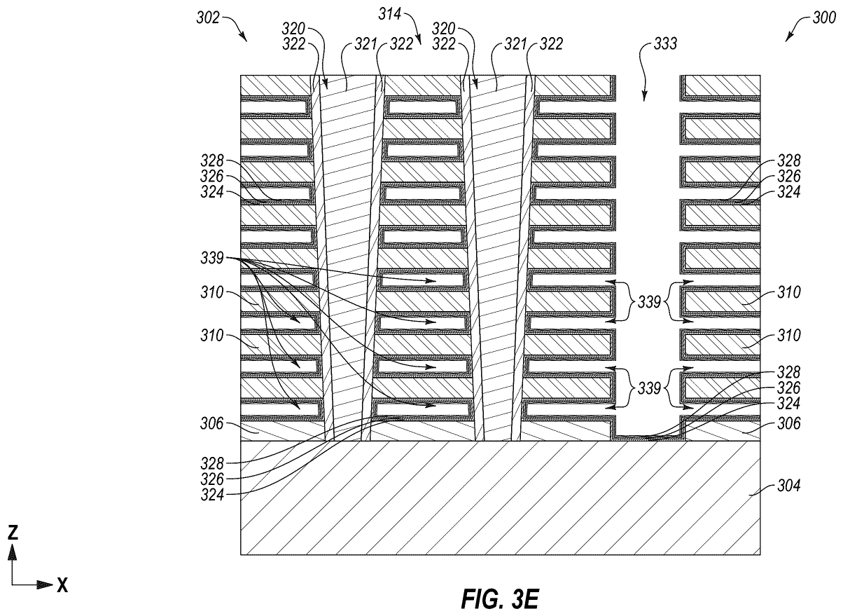

The boron-containing material 124 may be a chemical compound that includes boron and one or more other chemical elements. The boron-containing material 124 may be a boron oxide material (BₓO_{y}), a silicon boride material (SiₓB_{y}), a silicon boron oxide material (SiₓB_{y}O_{z}), or a combination thereof. The boron-containing material 124 may be a stoichiometric compound or a non-stoichiometric compound, and values of “x” and “y” may be integers or may be non-integers. The boron-containing material 124 may include boron hydride in addition to the boron oxide material, the silicon boride material, or the silicon boron oxide material. As non-limiting examples, the boron oxide material may include, but is not limited to, boron trioxide (B₂O₃), boron suboxide (B₆O), or a combination thereof. As non-limiting examples, the silicon boride material may include, but is not limited to, hexaboron silicide (B₆Si), silicon hexaboride (SiB₆), silicon tetrabromide (SiB₄), silicon triboride (SiB₃), or a combination thereof. The silicon boron oxide material may include silicon boride and silicon oxide. In additional embodiments, the boron-containing material 124 includes boron hydride (BₓH_{y}) in addition to the boron oxide material, the silicon boride material, and/or the silicon boron oxide material. As a non-limiting example, the boron-containing material 124 may include diborane (B₂H₆). In some embodiments, the boron-containing material 124 comprises boron trioxide (B₂O₃). In further embodiments, the boron-containing material 124 comprises boron suboxide (B₆O). The boron-containing material 124 may be formed by reaction of a precursor (e.g., precursor 334 below in FIG. 3C) of the boron-containing material 124 with residues produced during formation of the microelectronic device 100. Additional process acts may be conducted to convert a portion or all of the boron-containing material 124 to boron oxide.

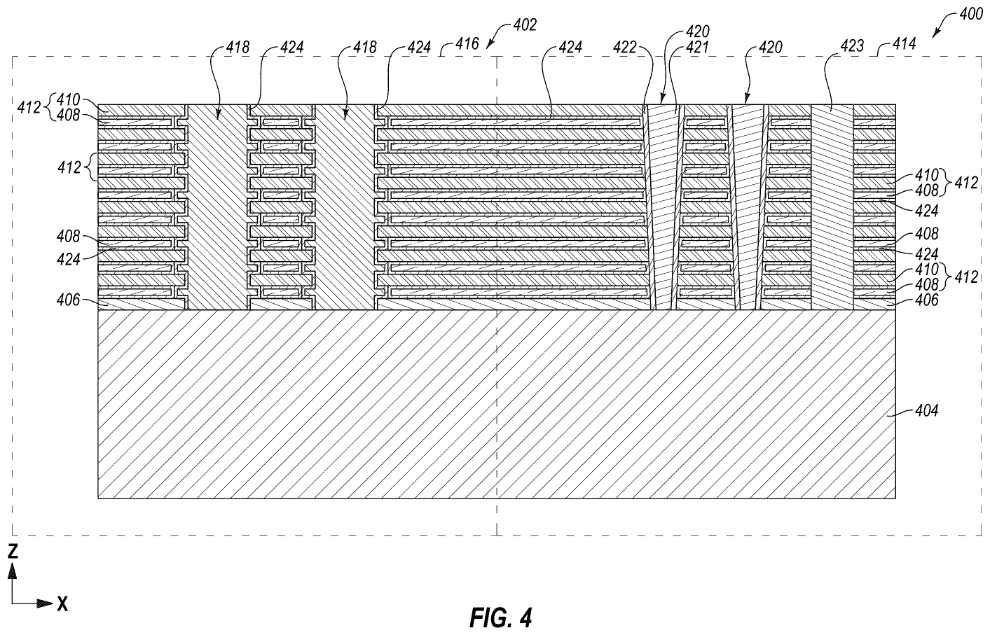

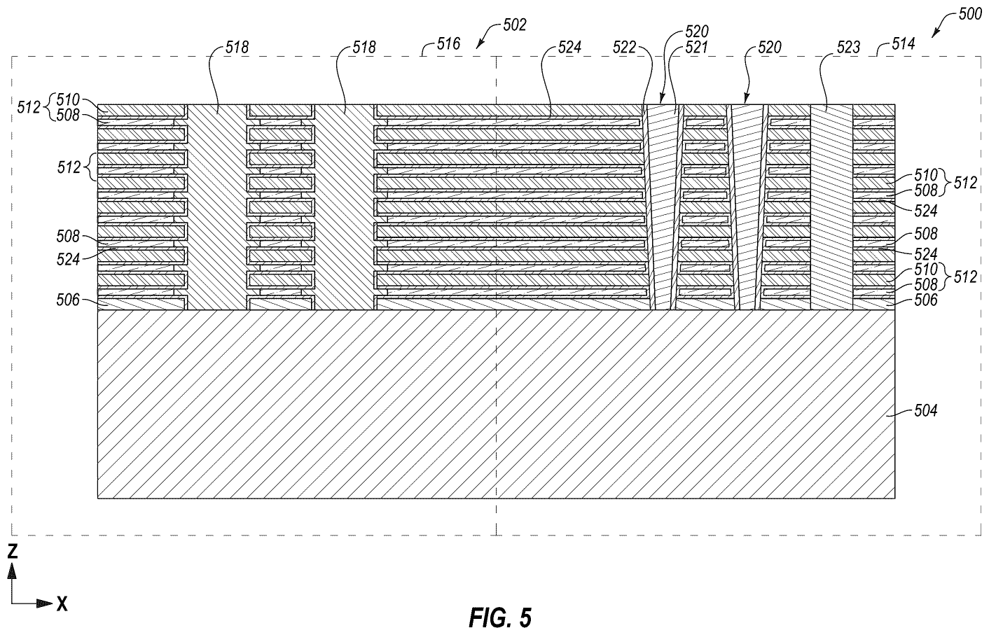

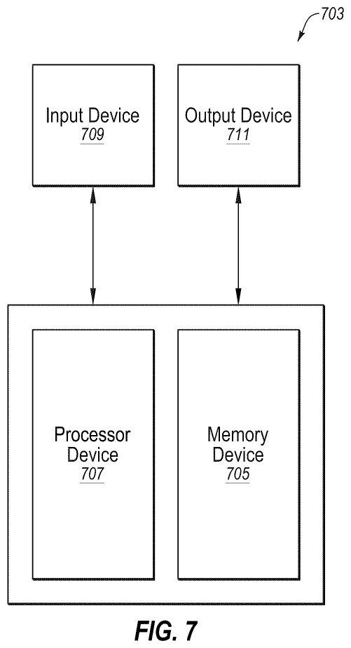

The precursor of the boron-containing material 124 may react with and/or remove residues remaining from process acts conducted during formation of the microelectronic device 100. The boron-containing material 124 may be further converted to boron oxide by subsequent process acts. The resulting boron-containing material 124 may substantially prevent or reduce diffusion of halide compounds (e.g., compounds of fluorine, chlorine, bromine, iodine) from the conductive structures 108 to the dielectric structures 110. Thus, the boron-containing material 124 may substantially prevent or reduce the formation of voids within the dielectric structures 110, and may improve the performance and/or longevity of the microelectronic device 100. The performance and/or longevity of microelectronic devices (e.g., the microelectronic device 100 (FIG. 1), the microelectronic device 400 of FIG. 4 below, the microelectronic device 500 of FIG. 5 below) and/or electronic systems (e.g., electronic system 703 of FIG. 7 below) including the including boron-containing material 124 may also be improved.

Thus, in accordance with embodiments of the disclosure, a microelectronic device comprises a stack structure, a memory pillar, and a boron-containing material. The stack structure comprises alternating conductive structures and dielectric structures. The memory pillar extends through the stack structure and defines memory cells at intersections of the memory pillar and the conductive structures. The boron-containing material is on at least a portion of the conductive structures of the stack structure.

FIGS. 3A-3E are simplified, partial cross-sectional views illustrating a microelectronic device 300 at different processing stages of a method of forming the microelectronic device 100 in accordance with embodiments of the disclosure. In FIGS. 3A-3E and the associated description, functionally similar features (e.g., structures, materials) to those of the microelectronic device 100 of FIGS. 1 and 2 are referred to with similar reference numerals incremented by 200. To avoid repetition, not all features shown in FIGS. 3A-3E are described in detail herein. Rather, unless described otherwise below, a feature as shown in FIGS. 3A-3E designated by a reference numeral that is a 200 increment of the reference numeral of a previously described feature will be understood to be substantially similar to the previously described feature.

For simplicity, FIGS. 3A-3E show only an array region 314 of the microelectronic device 300. However, it is understood that a contact region similar to the contact region 116 of FIG. 1 is present horizontally adjacent to the array region 314. The contact region includes contact structures that may be formed before, or during the formation of the boron-containing material 324 (e.g., the boron-containing material 124 of FIGS. 1 and 2) horizontally neighboring dielectric structures 310 of a stack structure 302, as shown and described below with reference to FIG. 4.

Referring collectively to FIGS. 3A-3E, the microelectronic device 300 comprises the stack structure 302 (e.g., a preliminary stack structure) and one or more memory pillars 320 (e.g., vertical strings of memory cells) extending through the stack structure 302. The microelectronic device 300 may also include a source 304 vertically underlying (e.g., in the Z-direction) the stack structure 302. The stack structure 302 includes a base material 306 vertically overlying (e.g., in the Z-direction) the source 304, and a vertically alternating (e.g., in the Z-direction) sequence of sacrificial structures 338 and dielectric structures 310 arranged in tiers 312 on the base material 306. Each of the tiers 312 of the stack structure 302 comprises one of the sacrificial structures 338 and one of the vertically neighboring dielectric structures 310. The stack structure 302 and the memory pillars 320 may be formed by conventional techniques. Additionally, an etch stop material (not shown) may be formed to cover the memory pillars 320, which may prevent removal process acts from affecting the memory pillars 320.

The sacrificial structures 338 may include dielectric structures similar to the dielectric structures 310, but the sacrificial structures 338 may be selectively removable (e.g., selectively etchable) relative to the dielectric structures 310. For example, the sacrificial structures 338 may comprise a dielectric nitride material if the dielectric structures 310 comprise a dielectric oxide material. The sacrificial structures 338 are subsequently removed and replaced with the conductive material of the conductive structures 108 shown in FIGS. 1 and 2.

Referring now to FIG. 3A, one or more slits 333 (which may also be referred to as “slots” or “replacement gate slots”) may be formed within the stack structure 302 at a location corresponding to the ultimate location of a dielectric fill material (e.g., the dielectric fill material 123 of FIGS. 1 and 2) to be formed therein. The slit 333 may extend at least partially into the stack structure 302. For example, the slit 333 may vertically (e.g., in the Z-direction) extend through all of the tiers 312 and/or the base material 306, and the slit 333 may terminate at the source 304, as shown. The slit 333 may be formed by one or more etch processes. After forming the slit 333, side surfaces of the sacrificial structures 338 and the dielectric structures 310 within the slit 333 are substantially coplanar. The slit 333 may divide the microelectronic device 300 into separate blocks, each block including multiple memory pillars 320.

Referring now to FIG. 3B, after forming the slit 333, the sacrificial structures 338 (FIG. 3A) of the stack structure 302 may be removed using the slit 333 as part of a so-called “replacement gate” or “gate last” process. By way of non-limiting example, the sacrificial structures 338 may be removed by exposing the sacrificial structures 338 to a wet etchant comprising one or more of phosphoric acid, sulfuric acid, hydrochloric acid, nitric acid, or another etch chemistry. In some embodiments, the sacrificial structures 338 are removed by exposing the sacrificial structures 338 to a so-called “wet nitride strip” comprising a wet etchant comprising phosphoric acid.

Removal of the sacrificial structures 338 produces openings 339 between the dielectric structures 310 of the stack structure 302. Additionally, during the formation of the openings 339, residues (not shown) produced by the etch conditions (e.g., etch chemistry, process conditions) may be formed and remain on exposed surfaces of the dielectric structures 310 and/or the memory pillars 120 within the openings 339 of the stack structure 302. The residues may include, but are not limited to, various chemical species that are reactive with a precursor 334 of a boron-containing material 324, as shown in FIG. 3C. The precursor 334 of the boron-containing material 324 may be formulated to react with one or more of the residues, forming the boron-containing material 324.

Referring now to FIG. 3C, the boron-containing material 324 may be formed (e.g., deposited) on the exposed surfaces of the dielectric structures 310 following exposure of the precursor 334 to the residues. The boron-containing material 324 may also be formed on the exposed surfaces within the openings 339 of the stack structure 302. For example, the boron-containing material 324 may be formed on the exposed vertical surfaces of the dielectric structures 310, the horizontal surfaces of the dielectric structures 110 of the stack structure 302, and the exposed vertical surfaces of the memory pillars 320 within the openings 339. The boron-containing material 324 may partially fill the openings 339, such as by forming conformally on the exposed surfaces defining the openings 339 and the slit 333. To form the boron-containing material 324, side surfaces of the dielectric structure 310 within the slit 333, exposed horizontal surfaces of the dielectric structures 310, and exposed vertical surfaces of the memory pillars 320 within the openings 339 are each exposed to the precursor 334 of the boron-containing material 324. The precursor 334 of the boron-containing material 324 may be a boron-containing gas (e.g., diborane (B₂H₆) or boric acid (H₃BO₃)) that is reactive with at least some of the residues present in the openings 339. For example, the boron-containing material 324 may be conformally formed on exposed vertical side surfaces and exposed horizontal surfaces of the dielectric structures 310, exposed vertical side surfaces and horizontal surfaces of the base material 306, an exposed upper horizontal surface of the source 304, and/or on exposed vertical side surfaces of the memory pillars 320. Accordingly, the boron-containing material 324 is conformally formed on exposed surfaces of the stack structure 302, the base material 306, the source 304, and vertical portions of the memory pillars 320.

The boron-containing material 324 may be formed by positioning the microelectronic device 300 of FIG. 3B within a chamber that is pressurized at from about 10 Ton to about 100 Ton, and maintained at a temperature of from about 20° C. to about 600° C. The temperature within the chamber may range from about 20° C. to about 400° C., from about 100° C. to about 400° C., from about 100° C. to about 500° C., from about 100° C. to about 600° C., from about 100° C. to about 600° C., from about 300° C. to about 600° C., or from about 500° C. to about 600° C. The precursor 334 of the boron-containing material 324 may be introduced (e.g., flowed) into the chamber at a rate of from about 1 standard cubic centimeters per minute (SCCM) to about 10,000 SCCM. The precursor 334 reacts with the residues, forming the boron-containing material 324 and volatile species, which are removed from the chamber. The thickness of the boron-containing material 324 may depend on the process conditions used to form the boron-containing material 324. By adjusting the duration of time to which the microelectronic device 300 is exposed to the precursor 334 and/or the temperature within the chamber, the boron-containing material 324 may be formed at a desired thickness. For instance, the thickness of the boron-containing material 324 may be increased by increasing the exposure time and/or temperature within the chamber.

The precursor 334 of the boron-containing material 324 reacts with the residues to conformally form the resulting boron-containing material 324. The boron-containing material 324 may include elemental boron, polymeric boron, and/or a boron-containing compound, such as boron oxide. The boron-containing material 324 may include a substantially homogeneous chemical composition throughout its thickness or a substantially heterogeneous chemical composition throughout its thickness. In some embodiments, the boron-containing material 324 exhibits a substantially homogeneous composition of elemental boron, of polymeric boron, or of the boron-containing compound. In additional embodiments, the boron-containing material 324 exhibits a heterogeneous chemical composition, such as including portions of elemental boron, polymeric boron, and/or the boron-containing compound. For example, in some embodiments, the boron-containing material 324 comprises a bi-layer of elemental boron and boron oxide. The elemental boron may, for example, be present proximal to the dielectric structures 310 of the stack structure 302 and proximal to vertical portions of the memory pillars 320, and the boron oxide may be present distal to the dielectric structures 310 of the stack structure 302 and distal to the vertical portions of the memory pillars 320. In other words, the boron oxide of the boron-containing material 324 may the outermost material within the openings 339 and/or the slit 333.

Alternatively, the boron-containing material 324 may include elemental boron as initially formed and at least a portion of the elemental boron may be converted to boron oxide as a result of one or more subsequent processing acts, such as the subsequent formation of other materials of the microelectronic device 300. The initially formed, boron-containing material 324 may be converted to boron oxide by the process conditions used in the formation of the barrier material 326 (see FIG. 3D). Some or all of the elemental boron may, for example, be converted to boron oxide after forming a dielectric (e.g., metal oxide) material as the barrier material 326. The relative thickness of the elemental boron and the boron oxide may depend on the process conditions used to form the other materials of the microelectronic device 300.

Referring now to FIG. 3D, a barrier material 326 (e.g., the barrier material 126 of FIGS. 1 and 2) may be formed (e.g., disposed, deposited) on the boron-containing material 324 within the slit 333 and within the openings 339. The barrier material 326 may at least partially fill the openings 339. The barrier material 326 may exhibit substantially uniform dimensions (e.g., thicknesses) in the X-direction and the Y-direction. The barrier material 326 may, for example, be conformally formed on the boron-containing material 324.

The barrier material 326 may be formed of and include a dielectric material. In some embodiments, the barrier material 326 may be formed of and include one or more of a dielectric oxide material. In some embodiments, the barrier material 326 comprises a high-k material. In some embodiments, the barrier material 326 comprises a high quality, conformal oxide, such as a high-k conformal metal oxide (e.g., aluminum oxide). Accordingly, in some embodiments, the barrier material comprises a conformal aluminum oxide (Al₂O₃) material.

Although the barrier material 326 is shown and described in FIG. 3D as being formed on the boron-containing material 324, the disclosure is not so limited. For example, the barrier material 326 may initially be formed within the openings 339, and then the boron-containing material 324 may be formed on the barrier material 326. In other words, the locations of the boron-containing material 324 and the barrier material 326 shown in FIG. 3 may be reversed.

Referring now to FIG. 3E, a liner material 328 (e.g., the liner material 128 of FIGS. 1 and 2) may be formed (e.g., disposed, deposited) on the barrier material 326 within the slit 333 and within the openings 339. The liner material 328 may at least partially fill the openings 339. The liner material 328 may exhibit substantially uniform dimensions (e.g., thicknesses) in the X-direction and the Y-direction. The liner material 328 may, for example, be conformally formed on the barrier material 326.

The liner material 328 may comprise a seed material from which or upon which conductive structures (e.g., the conductive structures 108 of FIGS. 1 and 2) may be formed. The liner material 328 may be formed of and include, for example, a metal (e.g., titanium, tantalum), a metal nitride (e.g., tungsten nitride, titanium nitride, tantalum nitride), or another material.

The conductive structures 108 may be formed between the adjacent dielectric structures 110 at locations corresponding to the previous locations of the sacrificial structures 338, forming the tiers 112 of alternating levels of the conductive structures (e.g., the conductive structures 108 of FIGS. 1 and 2), the dielectric structures 110, and memory pillars 120 including strings of memory cells (e.g., the memory cells 125 of FIG. 2) extending through the stack structure 302.

Portions of the boron-containing material 324, the barrier material 326, and/or the liner material 328 on vertical sidewalls of the dielectric structures 310 within the slit 333 may be removed such that exposed surfaces within the slit 333 are substantially free of the boron-containing material 324, the barrier material 326, and/or the liner material 328. The slit 333 may then be filled with a dielectric fill material (e.g., the dielectric fill material 123 of FIGS. 1 and 2).

During removal of the sacrificial structures 338 (FIG. 3A) and formation of the conductive structures (e.g., the conductive structures 108 of FIGS. 1 and 2), halide compounds, such as hydrogen fluoride, may be produced. If the halide compound was to diffuse through a conventional microelectronic device, voids are formed in the dielectric structures of the stack structure. However, the presence of the boron-containing material 124, 324 within the microelectronic devices 100, 300 described herein reduces or eliminates the diffusion of halide compounds, which reduces the formation of voids in the dielectric structures (e.g., the dielectric structures 110, 310). Without being bound by any theory, it is believed that the boron-containing material (e.g., the boron-containing material 124, 324) functions as a barrier to the halide compounds. The presence of the boron-containing material 124, 324 and corresponding reduction in voids reduces shorts and leakage electrical failures between the conductive structures 108 and/or the memory pillars (e.g., the memory pillars 120, 320) including strings of the memory cells 125. The boron-containing material 124, 324 also reduces wordline to wordline leakage. In addition, the presence of the boron-containing material 124, 324 may reduce process delays associated with nucleation of the barrier material 126, 326, which provides increased step coverage.

Thus, in accordance with embodiments of the disclosure, a method of forming a microelectronic device comprises forming a slit within an array region of a stack structure comprising vertically alternating sacrificial structures and dielectric structures. The method additionally comprises removing the sacrificial structures through the slit to form openings between vertically neighboring dielectric structures. The method further comprises forming a boron-containing material on exposed surfaces of the dielectric structures of the stack structure. The method additionally comprises forming a conductive material within the openings.

FIG. 4 is a simplified, partial cross-sectional view illustrating a microelectronic device 400, in accordance with embodiments of the disclosure. In FIG. 4 and the associated description, functionally similar features (e.g., structures, materials) to those of the microelectronic device 100 of FIGS. 1 and 2 are referred to with similar reference numerals incremented by 300. To avoid repetition, not all features shown in FIG. 4 are described in detail herein. Rather, unless described otherwise below, a feature as shown in FIG. 4 designated by a reference numeral that is a 300 increment of the reference numeral of a previously described feature will be understood to be substantially similar to the previously described feature.

Referring now to FIG. 4, the microelectronic device 400 may include a boron-containing material 424 in portions of a stack structure 402. For example, the boron-containing material 424 may be on and/or between conductive structures 408 and/or dielectric structures 410 within an array region 414 and a contact region 416 of the stack structure 402. Additionally, the boron-containing material 424 may be present on and between the contact structures 418 and sidewalls of the stack structure 402. For example, the boron-containing material 424 may be on vertical surfaces of the contact structures 418, vertical surfaces of the conductive structures 408, and on vertical surfaces of the dielectric structures 410. In embodiments in which portions of the conductive structures 408 of the stack structure 402 have been recessed, as shown, the contact structures 418 may have protruding portions that correspond to the shape of the recesses, and the boron-containing material 424 may be present between the protruding portions of the contact structures 418 and the stack structure 402.

In some embodiments, portions of the boron-containing material 424 between the contact structures 418 and the sidewalls of the stack structure 402 may be formed before remaining portions of the boron-containing material 424 are formed utilizing the “replacement gate” process shown and described above with reference to FIGS. 3A-3E. For instance, the boron-containing material 424 in the contact region 416 and the array region 414 may be formed at the same time or at different times. However, the disclosure is not so limited, and portions of the boron-containing material 424 between the contact structures 418 and the sidewalls of the stack structure 402 may be formed at the same time as the replacement gate process, as shown and described below with reference to FIG. 5.

To form the first portions of the boron-containing material 424 between the contact structure 418 and the sidewalls of the stack structure 402 as shown in FIG. 4, a preliminary stack structure (e.g., a preliminary structure (not shown) of the stack structure 402) may be provided that includes alternating sacrificial structures and the dielectric structures 410 arranged in tiers 412. Vertical contact openings for the contact structures 418 may be formed within the preliminary stack structure by one or more etch processes. Forming the vertical contact openings may also horizontally recess portions of the sacrificial structures relative to the dielectric structures 410 of the preliminary stack structure.

A boron-containing precursor (e.g., the boron-containing precursor 334 of FIG. 3C) may be introduced within the contact openings of the preliminary stack structure and may form (e.g., conformally form) the boron-containing material 424 on the sidewalls of the stack structure, including the recesses. The precursor of the boron-containing material 424 may react with and/or remove residues remaining from etch process acts conducted to form the contact openings, resulting in the first portions of the boron-containing material 424 between the contact structure 418 and the sidewalls of the preliminary stack structure. Because the first portions of the boron-containing material 424 may be subjected to additional etch processes during the “replacement gate” process described in FIGS. 3A-3E, the first portions of the boron-containing material 424 may be selected to be resistant to removal in response to exposure to etch chemistries formulated and configured to remove the sacrificial structures of the preliminary stack structure.

The contact structures 418 may then be formed within the remainder of the contact openings. Once the contact structures 418 are formed, the microelectronic device 400 may undergo the “replacement gate” process described in FIGS. 3A-3E to form the microelectronic device 400, including the boron-containing material 424 within the stack structure 402 comprising vertically alternating tiers 412 of conductive structures 408 and dielectric structures 410, as shown in FIG. 4.

The resulting boron-containing material 424 may include vertical portions separating the contact structures 418 from the conductive structures 408 as a result of the first portions of the boron-containing material 424 (e.g., between the contact structures 418 and sidewalls of the stack structure 402) being formed before the remaining portions of the boron-containing material 424. The resulting boron-containing material 424 may substantially reduce or prevent diffusion of halide compounds (e.g., compounds of fluorine, chlorine, bromine, iodine) from the contact structures 418 and/or the conductive structures 408 to dielectric structures 410 of the stack structure 402. Thus, the boron-containing material 124 may substantially prevent or reduce the formation of voids within the dielectric structures 410, and may improve the performance and/or longevity of the microelectronic device 400.

FIG. 5 is a simplified, partial cross-sectional view illustrating a microelectronic device 500, in accordance with embodiments of the disclosure. In FIG. 5 and the associated description, functionally similar features (e.g., structures, materials) to those of the microelectronic device 400 of FIG. 4 are referred to with similar reference numerals incremented by 100. To avoid repetition, not all features shown in FIG. 4 are described in detail herein. Rather, unless described otherwise below, a feature as shown in FIG. 5 designated by a reference numeral that is a 100 increment of the reference numeral of FIG. 4 will be understood to be substantially similar to the previously described feature of FIG. 4.

Referring now to FIG. 5, the microelectronic device 500 includes a boron-containing material 524 without vertical portions of the boron-containing material 524 separating contact structures 518 from conductive structures 508 of a stack structure 502, in contrast to the microelectronic device 400 of FIG. 4. The microelectronic device shown in FIG. 5 has been simplified to illustrate the difference in locations of the boron-containing material between FIGS. 4 and 5. For example, although not illustrated in FIG. 5, it is understood that a dielectric material (e.g., the barrier material 126, 326) is present between the contact structure 518 and the conductive structures 508.

In FIG. 5, contact openings for the contact structures 518 within the stack structure 502 may be formed at the same time that the microelectronic device 500 undergoes the “replacement gate” process previously described with reference to FIGS. 3A-3E.

To form the boron-containing material 524, a preliminary stack structure (e.g., a preliminary structure of the stack structure 502) may be provided that includes alternating sacrificial structures and the dielectric structures 510 arranged in tiers 512. Vertical contact openings for the contact structures 518 may be formed within the preliminary stack structure by one or more etch processes. Forming the vertical contact openings may also horizontally recess portions of the sacrificial structures relative to the dielectric structures 510 of the preliminary stack structure. A slit (e.g., slit 333 of FIGS. 3A-3E) may also be formed within and extending through the preliminary stack structure.

The boron-containing precursor (e.g., the boron-containing precursor 334 of FIG. 3C) material may be introduced into the preliminary stack structure via the slits and the contact openings to form the boron-containing material 524 conforming to the geometry of the sidewalls of the contact openings and the slits, and may also result in the boron-containing material 524 continuously extending along the dielectric structures 510 of the stack structure. The precursor of the boron-containing material 524 may react with and/or remove residues remaining from process acts conducted during formation of the microelectronic device 500. The boron-containing material 524 may be further converted to boron oxide by subsequent process acts. Accordingly, in some embodiments the boron-containing material 524 may be uninterrupted (e.g., continuous) along entire horizontal surfaces of the dielectric structures 510 (e.g., from the contact structures 518 to the memory pillars 520).

The resulting boron-containing material 524 may substantially prevent or reduce diffusion of halide compounds (e.g., compounds of fluorine, chlorine, bromine, iodine) from the contact structure 518 and/or conductive structures 508 to dielectric structures 510 of the stack structure 502. Thus, the boron-containing material 524 may substantially prevent or reduce the formation of voids within the dielectric structures 510, and may improve the performance and/or longevity of the microelectronic device 500.

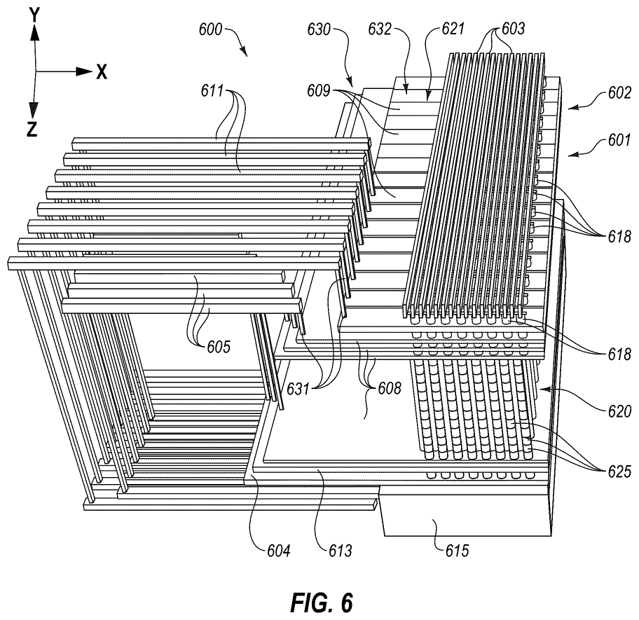

FIG. 6 illustrates a partial cutaway perspective view of a microelectronic device 600. The microelectronic device 600 may include a memory device 601 (e.g., a memory device, such as a dual deck 3D NAND Flash memory device) that includes the boron-containing material 124, 324, 424, 524 described above.

Referring now to FIG. 6, the microelectronic device 600 may be substantially similar to the microelectronic devices 100, 400, 500 following the processing stages previously described with reference to FIG. 3A through FIG. 3E. As shown in FIG. 6, the microelectronic device 600 may include a stack structure 602 that includes a staircase structure 630 defining contact regions for connecting access lines 605 to conductive structures 608. The microelectronic device 600 may include memory pillars 620 defining memory cells 625 that are coupled to each other in series. The memory pillars 620 may extend vertically (e.g., in the Z-direction) and orthogonally to the conductive structures 608, such as data lines 603, a source 604, the conductive structures 608, the access lines 605, first select gates 609 (e.g., upper select gates, drain select gates (SGDs)), select lines 611, and a second select gate 613 (e.g., a lower select gate, a source select gate (SGS)). The select gates 609 may be horizontally divided (e.g., in the Y-direction) into multiple block structures 632 and sub-blocks horizontally separated (e.g., in the Y-direction) from one another by slot structures 621.

Vertical conductive contacts 631 may electrically couple components to each other as shown. For example, the select lines 611 may be electrically coupled to the first select gates 609 and the access lines 605 may be electrically coupled to the conductive structures 608. The memory device 601 may also include a control unit 615 positioned under the memory array, which may include control logic devices configured to control various operations of other features (e.g., the memory cells 625 of the memory pillars 620) of the memory device 601. By way of non-limiting example, the control unit 615 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers), decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. The control unit 615 may be electrically coupled to the data lines 603, the source 604, the access lines 605, the first select gates 609, and the second select gates 613, for example. In some embodiments, the control unit 615 includes CMOS (complementary metal-oxide-semiconductor) circuitry. In such embodiments, the control unit 615 may be characterized as having a “CMOS under Array” (“CuA”) configuration.

The first select gates 609 may extend horizontally in a first direction (e.g., the X-direction) and may be coupled to respective first groups of memory pillars 620 at a first end (e.g., an upper end) of the memory pillars 620. The second select gate 613 may be formed in a substantially planar configuration and may be coupled to the memory pillars 620 at a second, opposite end (e.g., a lower end) of the memory pillars 620.

The data lines 603 (e.g., bit lines) may extend horizontally in a second direction (e.g., in the Y-direction) that is at an angle (e.g., perpendicular) to the first direction in which the first select gates 609 extend. The data lines 603 may be coupled to respective second groups of the memory pillars 620 at the first end (e.g., the upper end) of the memory pillars 620. A first group of memory pillars 620 coupled to a respective first select gate 609 may share a particular memory pillar 620 with a second group of memory pillars 620 coupled to a respective data line 603. Thus, a particular memory pillar 620 may be selected at an intersection of a particular first select gate 609 and a particular data line 603. Accordingly, the first select gates 609 may be used for selecting memory cells 625 of the memory pillars 620.

The conductive structures 608 may extend in respective horizontal planes. The conductive structures 608 may be stacked vertically, such that each conductive structure 608 is coupled to all of the memory pillars 620 of memory cells 625, and the memory pillars 620 of the memory cells 625 extend vertically through the stack of conductive structures 608. The conductive structures 608 may be coupled to or may form control gates of the memory cells 625 to which the conductive structures 608 are coupled. Each conductive structure 608 may be coupled to one memory cell 625 of a particular memory pillar 620.

The staircase structure 630 may be configured to provide electrical connection between the access lines 605 and the conductive structures 608 through the vertical conductive contacts 631. In other words, a particular level of the conductive structures 608 may be selected via an access line 605 in electrical communication with a respective vertical conductive contact 631 in electrical communication with the particular conductive structure 608.

The data lines 603 may be electrically coupled to the memory pillars 620 through conductive contact structures 618.

Memory devices (e.g., the memory device 601 of FIG. 6) and microelectronic devices (e.g., the microelectronic devices 100, 400, 500 of FIGS. 1, 2, 4, and 5) of the disclosure may be included in embodiments of electronic systems of the disclosure. For example, FIG. 7 is a block diagram of an electronic system 703, in accordance with embodiments of the disclosure.

Referring now to FIG. 7, the electronic system 703 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 703 includes at least one memory device 705. The memory device 705 may include, for example, an embodiment of a memory device herein (e.g., the memory device 601 of FIG. 6) and/or a microelectronic device (e.g., the microelectronic device 100, 400, 500) previously described herein.

The electronic system 703 may further include at least one electronic signal processor device 707 (often referred to as a “microprocessor”). The electronic signal processor device 707 may, optionally, include an embodiment of one or more of a memory device and a microelectronic device previously described herein. The electronic system 703 may further include one or more input devices 709 for inputting information into the electronic system 703 by a user, such as, for example, a mouse or other pointing device, a keyboard, a touchpad, a button, or a control panel. While the memory device 705 and the electronic signal processor device 707 are depicted as two (2) separate devices in FIG. 7, in additional embodiments, a single (e.g., only one) memory/processor device having the functionalities of the memory device 705 and the electronic signal processor device 707 is included in the electronic system 703. In such embodiments, the memory/processor device may include one or more of a microelectronic device (e.g., the microelectronic device 100 of FIGS. 1 and 2) and a memory device (e.g., the memory device 601 of FIG. 4) previously described herein. In some embodiments, the memory device 705 of the electronic system 703 comprises strings of memory cells (e.g., the memory pillars 620 defining the memory cells 625 of FIG. 6) vertically extending through a stack structure (e.g., the stack structure 102, 402).

The electronic system 703 may further include one or more output devices 711 for outputting information (e.g., visual or audio output) to a user such as, for example, a monitor, a display, a printer, an audio output jack, a speaker, etc. In some embodiments, the input device 709 and the output device 711 may comprise a single touchscreen device that can be used both to input information to the electronic system 703 and to output visual information to a user. The input device 709 and the output device 711 may communicate electrically with one or more of the memory device 705 and the electronic signal processor device 707.

Thus, in accordance with embodiments of the disclosure, an electronic system comprises an input device, an output device, a processor, and a memory device. The processor is operably coupled to the input device and the output device. The memory device is operably coupled to the processor device and comprises a microelectronic device. The microelectronic device comprises a stack structure, a memory pillar, and a boron-containing material. The stack structure comprises vertically alternating conductive structures and dielectric structures. The memory pillar extends through the stack structure. The boron-containing material is between the conductive structures and the dielectric structures of the stack structure. Portions of the boron-containing material separate the conductive structures from the memory pillar.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

The methods of the disclosure may facilitate the formation of microelectronic devices (e.g., memory devices) and systems (e.g., electronic systems) having one or more of increased performance, increased efficiency, increased reliability, and increased durability as compared to conventional devices (e.g., conventional memory devices) and conventional systems (e.g., conventional electronic systems).

While the disclosure is susceptible to various modifications and alternative forms, specific embodiments have been shown by way of example in the drawings and have been described in detail herein. However, the disclosure is not intended to be limited to the particular forms disclosed. Rather, the disclosure is to cover all modifications, equivalents, and alternatives falling within the scope of the disclosure as defined by the following appended claims and their legal equivalents. For example, elements and features disclosed in relation to one embodiment of the disclosure may be combined with elements and features disclosed in relation to other embodiments of the disclosure.

What is claimed is:

1. A microelectronic device, comprising:
a stack structure comprising alternating conductive structures and dielectric structures;
a memory pillar extending through the stack structure and defining memory cells at intersections of the memory pillar and the conductive structures; and
a boron-containing material on at least a portion of the conductive structures of the stack structure.

2. The microelectronic device of claim 1, wherein the boron-containing material is on horizontal surfaces of the conductive structures.

3. The microelectronic device of claim 1, wherein the boron-containing material is on at least a portion of the memory pillar and horizontal surfaces of the dielectric structures.

4. The microelectronic device of claim 3, wherein the boron-containing material directly contacts a charge-blocking material of the memory pillar.

5. The microelectronic device of claim 1, further comprising a barrier material between the conductive structures and the dielectric structures. 6 The microelectronic device of claim 5, wherein horizontal surfaces of the boron-containing material directly contact horizontal surfaces of the barrier material.

7. The microelectronic device of claim 1, further comprising a liner material substantially surrounding the conductive structures, and a barrier material substantially surrounding the liner material.

8. The microelectronic device of claim 7, wherein the liner material and the barrier material are between the boron-containing material and the conductive structures.

9. The microelectronic device of claim 1, wherein the boron-containing material comprises elemental boron, polymeric boron, a boron oxide material, a silicon boride material, a silicon boron oxide material, or a combination thereof.

10. The microelectronic device of claim 1, wherein the boron-containing material separates the conductive structures of the stack structure from the dielectric structures of the stack structure.

11. The microelectronic device of claim 1, wherein the boron-containing material is present in an array region of the microelectronic device.

12. The microelectronic device of claim 1, further comprising a contact structure in a contact region of the stack structure, wherein the boron-containing material is between sidewalls of the stack structure and the contact structure.

13. A method of forming a microelectronic device, comprising:
forming a slit within an array region of a stack structure comprising vertically alternating sacrificial structures and dielectric structures and memory pillars;
removing the sacrificial structures through the slit to form openings between vertically neighboring dielectric structures;
forming a boron-containing material on exposed surfaces of the dielectric structures of the stack structure; and
forming a conductive material within the openings.

14. The method of claim 13, wherein forming the boron-containing material comprises exposing the dielectric structures of the stack structure to a gas comprising B₂H₆.

15. The method of claim 14, wherein exposing the dielectric structures of the stack structure to a gas comprises forming a conformal boron-containing material on horizontal surfaces of the dielectric structures and on vertical surfaces of the memory pillars.

16. The method of claim 13, further comprising forming a barrier material comprising a high-k dielectric material on the boron-containing material.

17. The method of claim 16, wherein forming a conductive material within the openings comprises forming a liner material on the barrier material.

18. The method of claim 13, wherein forming a slit within an array region of the stack structure further comprises:
forming contact openings within a contact region of the stack structure;
forming the boron-containing material on exposed surfaces of the stack structure within the contact openings; and
forming contact structures within the contact openings.

19. An electronic system, comprising:
an input device;
an output device;
a processor device operably coupled to the input device and the output device; and
a memory device operably coupled to the processor device, the memory device comprising a microelectronic device, comprising:
a stack structure comprising vertically alternating conductive structures and dielectric structures;
a memory pillar extending through the stack structure; and
a boron-containing material between the conductive structures and the dielectric structures of the stack structure, portions of the boron-containing material separating the conductive structures from the memory pillar.

20. The electronic system of claim 19, wherein the boron-containing material directly contacts surfaces of the memory pillar and dielectric structures of the stack structure.
